(19) United States
(12) Patent Application Publication
(10) Pub. No.: US 2026/0326439 A1
(43) Pub. Date: Oct. 22, 2026

(54) NOZZLE PLATE, LIQUID DROPLET EJECTION HEAD, AND LIQUID DROPLET EJECTION DEVICE

(71) Applicant: Konica Minolta, Inc., Tokyo (JP)

(72) Inventors: Mitsuru YOKOYAMA, Takatsuki-shi, Osaka (JP); Kouichi SAMESHIMA, Kyoto-shi, Kyoto (JP)

(21) Appl. No.: 19/114,101

(22) PCT Filed: Sep. 15, 2023
(86) PCT No.: PCT/JP2023/033808

§ 371 Date: Mar. 21, 2025

(30) Foreign Application Priority Data
Sep. 22, 2022 (JP) 2022-151232

(51) Int. Cl. B41J 2/14; C30B 29/06; C30B 29/66

(52) U.S. Cl. CPC B41J 2/1433; C30B 29/06; C30B 29/66; B41J 2002/14475

(57) ABSTRACT

A nozzle plate includes nozzle channels each having a nozzle opening on a first surface. The nozzle channels each include: a nozzle tapered part having a channel area gradually increasing from the first surface toward a second surface; and a straight communication part communicating with the nozzle tapered part and including opposing surfaces substantially parallel. The straight communication part has a length in a first direction along the opposing surfaces that is longer than a length in a second direction on the second surface. The nozzle tapered part includes: a tapered face inclined from an end in the first direction toward a center of the nozzle opening; and a pair of riser faces with the nozzle opening in between. The pair of riser faces is parallel to a nozzle central axis or inclined to form an angle smaller than an angle formed by the tapered part, with the axis.

### TECHNICAL FIELD

The present invention relates to a nozzle plate, a liquid droplet ejection head, and a liquid droplet ejection device.

### BACKGROUND ART

Conventionally, as described in Patent Document 1, nozzle channels having nozzle openings are formed in a nozzle plate of a droplet ejection head of a droplet ejection device. Then, liquid such as ink passes through a nozzle channel and is ejected as liquid droplets from the nozzle opening.

### CITATION LIST

### Patent Literature

Patent Document 1: Japanese Patent No. 5519263

### SUMMARY OF INVENTION

### Technical Problem

In order to form an image with higher resolution, it is necessary to arrange the nozzle openings in the nozzle plate with high density. On the other hand, in order to secure ejection characteristics of liquid droplets, it is necessary to secure a volume of the nozzle channel to some extent.

In order to secure the volume of the nozzle channels while increasing the density of the nozzle openings, the openings of the surface opposed to the liquid droplet ejection surface may have an elongated shape which is long in one direction. However, in the case where the openings are formed in an elongated shape, there is a tendency that more ejection defects are generated than in the nozzle channels in which the openings are formed in a square shape.

This is thought to be due to the shape of the meniscus in which the liquid largely returns inside the nozzle channel in a case where large droplets are ejected at a high speed. That is, in the case where the openings have an elongated shape, as shown in FIGS. 24A and 24B, how the meniscus spreads is different between the short side and the long side. As a result, it is considered that the shape of the meniscus becomes unstable and ejection failures occur.

The present invention has an object to provide a nozzle plate, a liquid droplet ejection head, and a liquid droplet ejection device that can achieve both an increase in the density of nozzle openings and suitable ejection properties.

### Solution to Problem

The invention of claim 1 is a nozzle plate including:
a plurality of nozzle channels, in each of which a nozzle opening for ejecting liquid droplets is formed on a first surface of a substrate,
wherein each of the plurality of nozzle channels includes:
   a nozzle tapered part having a channel area that gradually increases from the first surface toward a second surface that is opposite to the first surface, the channel area being a cross-sectional area perpendicular to a droplet ejection direction; and
   a straight communication part that communicates with an end of the nozzle tapered part on a side of the second surface and includes a pair of opposing surfaces substantially parallel to each other,
wherein the straight communication part has a length in a first direction along the pair of opposing surfaces that is longer than a length in a second direction perpendicular to the first direction on the second surface,
wherein the nozzle tapered part includes: a tapered face that is inclined from an end in the first direction toward a center of the nozzle opening; and a pair of riser faces with the nozzle opening in between, the pair of riser faces each forming a step,
wherein each of the pair of riser faces is a vertical surface parallel to a nozzle central axis or an inclined surface which forms, with the nozzle central axis, an angle smaller than an angle formed by the tapered part with the nozzle central axis.

The invention described in claim 2 is the nozzle plate described in claim 1,
wherein a distance between the pair of riser faces in a cross section in the first direction passing the center of the nozzle opening is equal to the length in the second direction.

The invention described in claim 3 is the nozzle plate described in claim 1 or 2,
wherein a length from the first surface to an end of the pair of riser faces on the side of the second surface is equal to or greater than a maximum height to which a meniscus rises.

The invention described in claim 4 is the nozzle plate described in claim 3,
wherein the length from the first surface to the end of the pair of riser faces on the side of the second surface is 20 μm or more.

The invention described in claim 5 is the nozzle plate described in claim 3,
wherein the length from the first surface to the end of the pair of riser faces on the side of the second surface is 60 μm or more.

The invention described in claim 6 is the nozzle plate described in claim 1 or 2,
wherein each of the nozzle channels includes a nozzle straight part continuous with an end of the nozzle tapered part on a side of the first surface;
wherein a surface of the nozzle straight part forms a substantially constant angle with an axis parallel to a nozzle central axis,
wherein a channel area of an end of the nozzle straight part on the side of the first surface is equal to or smaller than a channel area of an end of the nozzle straight part on the side of the second surface.

The invention described in claim 7 is the nozzle plate described in claim 1 or 2,
wherein the substrate is made of single-crystal silicon,
wherein the nozzle tapered part is formed of a part of a {100} plane and a {111} plane,
wherein the straight communication part is formed of a part of the {100} plane.

The invention of claim 8 is the nozzle plate described in claim 1 or 2, further including:
a planar part having a surface parallel to the first surface and the second surface between an end of the straight communication part on a side of the first surface side and an end of the nozzle tapered part on the side of the second surface.

The invention described in claim 9 is a liquid droplet ejection head to be mounted on a liquid droplet ejection device, the liquid droplet ejection head comprising:
the nozzle plate described in 1 or 2.

The invention of claim 10 is a liquid droplet ejection device comprising:
the liquid droplet ejection head described in 9.

### Advantageous Effects of Invention

According to the present invention, it is possible to provide a nozzle plate, a liquid droplet ejection head, and a liquid droplet ejection apparatus that can achieve both an increase in the density of nozzle openings and favorable ejection properties.

### BRIEF DESCRIPTION OF DRAWINGS

FIG. 1 This is a schematic perspective view of a liquid droplet ejection device.

FIG. 2 This is an exploded perspective view showing a main part of a liquid droplet ejection head.

FIG. 3 This is a perspective cross-sectional view of one nozzle channel according to the first embodiment.

FIG. 4A This is a side cross-sectional view taken along line IVA-IVA of FIG. 3.

FIG. 4B This is a side cross-sectional view taken along line IVB-IVB of FIG. 3.

FIG. 5 This is a side cross-sectional view of a nozzle channel having a plurality of riser parts.

FIG. 6A This is a side cross-sectional view showing how liquid is drawn into a nozzle channel of the present invention.

FIG. 6B This is a side cross-sectional view showing how liquid is drawn into a nozzle channel of the present invention.

FIG. 7 This is a side cross-sectional view and a plan view showing a method of manufacturing a nozzle plate according to the first embodiment.

FIG. 8 This is a perspective cross-sectional view of one nozzle channel according to the second embodiment.

FIG. 9A This is a side cross-sectional view taken along a line IXA-IXA of FIG. 8.

FIG. 9B This is a side cross-sectional view taken along a line IXB-IXB of FIG. 8.

FIG. 10A This is an example of a nozzle channel including a nozzle straight part according to the present invention.

FIG. 10B This is an example of a nozzle channel including a nozzle straight part according to the present invention.

FIG. 10C This is an example of a nozzle channel including a nozzle straight part according to the present invention.

FIG. 10D This is an example of a nozzle channel including a nozzle straight part according to the present invention.

FIG. 10E This is an example of a nozzle channel without a nozzle straight part according to the present invention.

FIG. 10F This is an example of a nozzle channel without a nozzle straight part according to the present invention.

FIG. 10G This is an example of a nozzle channel without a nozzle straight part according to the present invention.

FIG. 11 This is a side cross-sectional view and a plan view showing a method of manufacturing a nozzle plate according to the second embodiment.

FIG. 12A This is a perspective cross-sectional view of one nozzle channel according to another example.

FIG. 12B This is a perspective cross-sectional view of one nozzle channel according to another example.

FIG. 13 This is a side cross-sectional view of one nozzle channel according to another example.

FIG. 14 This is a perspective cross-sectional view of one nozzle channel according to another example.

FIG. 15 This is a side cross-sectional view and a plan view showing a method of manufacturing a nozzle plate according to another example.

FIG. 16A This is a side cross-sectional view of one nozzle channel and an intermediate structure serving as the nozzle channel according to Example 1, viewed from a long side.

FIG. 16B This is a plan view of one nozzle channel and an intermediate structure serving as the nozzle channel according to Example 1, viewed from an attachment surface side.

FIG. 17A This is a side cross-sectional view of one nozzle channel and an intermediate structure serving as the nozzle channel according to Example 2, viewed from a long side.

FIG. 17B This is a plan view of one nozzle channel and an intermediate structure serving as the nozzle channel according to Example 2, viewed from an attachment surface side.

FIG. 18A This is a side cross-sectional view of one nozzle channel and an intermediate structure serving as the nozzle channel according to Example 3, seen from a long side.

FIG. 18B This is a plan view of one nozzle channel and an intermediate structure serving as the nozzle channel according to Example 3, viewed from an attachment surface side.

FIG. 19A This is a side cross-sectional view of one nozzle channel and an intermediate structure serving as the nozzle channel according to Example 4, viewed from a long side.

FIG. 19B This is a plan view of one nozzle channel and an intermediate structure serving as the nozzle channel according to Example 4, viewed from an attachment surface side.

FIG. 20A This is a side cross-sectional view of one nozzle channel and an intermediate structure serving as the nozzle channel according to Example 5, viewed from a long side.

FIG. 20B This is a plan view of one nozzle channel and an intermediate structure serving as the nozzle channel according to Example 5, viewed from an attachment surface side.

FIG. 21A This is a side cross-sectional view of one nozzle channel and an intermediate structure serving as the nozzle channel according to comparative example 1, viewed from a long side.

FIG. 21B This is a plan view of one nozzle channel and an intermediate structure serving as the nozzle channel according to Comparative Example 1, viewed from an attachment surface side.

FIG. 22A This is a side cross-sectional view of one nozzle channel and an intermediate structure serving as the nozzle channel according to comparative example 2, viewed from a long side.

FIG. 22B This is a plan view of one nozzle channel and an intermediate structure serving as the nozzle channel according to Comparative Example 2, viewed from an attachment surface side.

FIG. 23A This is a side cross-sectional view of one nozzle channel and an intermediate structure serving as the nozzle channel according to Comparative Example 3, viewed from a long side.

FIG. 23B This is a plan view of one nozzle channel and an intermediate structure serving as the nozzle channel according to Comparative Example 3, viewed from an attachment surface side.

FIG. 24A This is a side cross-sectional view showing how liquid is drawn into a nozzle channel whose opening has an elongated shape and which does not include a riser face.

FIG. 24B This is a side cross-sectional view showing how liquid is drawn into a nozzle channel whose opening has an elongated shape and which does not include a riser face.

### DESCRIPTION OF EMBODIMENTS

In the following, preferred embodiments of the present invention will be described with reference to the drawings. However, the scope of the invention is not limited to the illustrated examples. In the following description, components having the same function and configuration are denoted by the same reference numerals, and description thereof is omitted.

In addition, Miller indices which describe crystal planes and directions are generally denoted as follows, and the present specification also complies with it.
(h k l): specific plane
{h k l}: equivalent plane
[h k l]: specific direction
<h k l>: equivalent direction

In addition, in the notation of Miller indices, as in (1) and (2) of the following Expression 1, a sign representing a negative index generally has a bar over the index. Provided that in the present specification, for convenience, they are expressed as the following (1′) and (2′).

[Expression 1]

(h k̅ l) (1)

[h k̅ l] (2)

(h−k l) (1′)

[h−k l] (2′)

### [Inkjet Recording Device]

First, as a liquid droplet ejection device according to the present embodiment, an example of a configuration of an inkjet recording device 1 that includes an inkjet head 10, which is a liquid droplet ejection head, is disclosed.

In the following description, as shown in the drawings, a conveyance direction of a recording medium P in the inkjet recording device 1 is defined as a front-back direction, and a direction orthogonal to the front-back direction on a conveyance surface of the recording medium P is defined as a right-left direction. An ink ejection direction, which is a direction perpendicular to the front-back direction and the right-left direction, is referred to as an upper-lower direction. Furthermore, the inkjet head 10 will also be described with directions based on a state in which the inkjet head 10 is attached to the inkjet recording device 1.

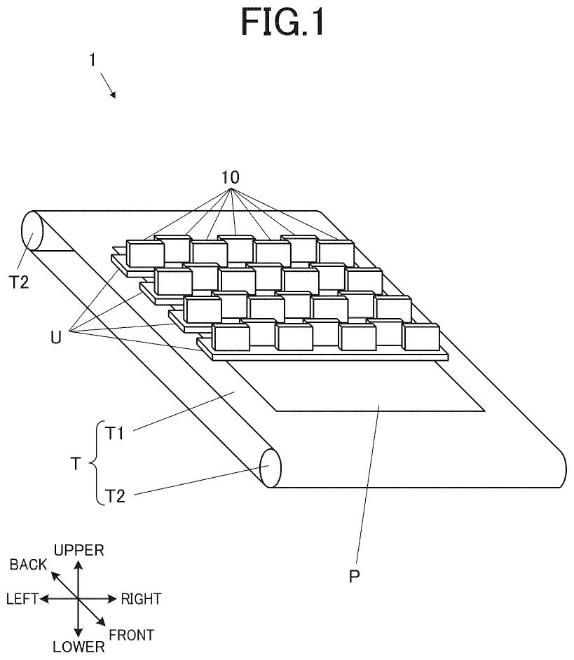

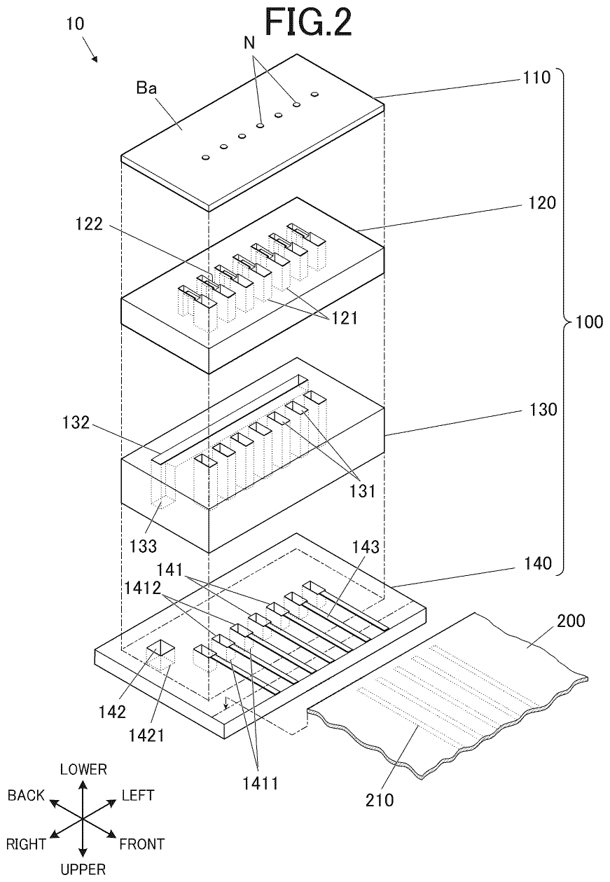

FIG. 1 is a schematic perspective view showing the inkjet recording device 1 according to the present embodiment. The inkjet recording device 1 conveys a recording medium P, such as a paper sheet, through the plurality of units U by a conveyance section T including, for example, a conveyance belt T1 and a conveyance roller T2. In each of the plurality of units U, a plurality of inkjet heads 10 are disposed. Each of the inkjet heads 10 performs printing on the recording medium P by ejecting ink of each color from nozzle openings N (refer to FIG. 2).

### <Inkjet Head>

FIG. 2 is an exploded perspective view showing a main configuration of one inkjet head 10.

Specifically, shown is a head chip 100 including a nozzle plate 110, a channel plate 120, a piezoelectric plate 130, and a wiring plate 140 in order from the bottom. FIG. 2 also shows a flexible printed circuit (FPC 200). The FPC 200 is electrically connected to the wiring plate 140.

In FIG. 2, the nozzle openings N are on the upper side, that is, turned upside down from FIG. 1.

### (Head Chip)

As shown in FIG. 2, the head chip 100 has a structure in which plates are stacked one above another.

Each of the nozzle plate 110, the channel plate 120, the piezoelectric plate 130, and the wiring plate 140 is a plate-like member having a substantially rectangular shape elongated in the right-left direction.

### {Nozzle Plate}

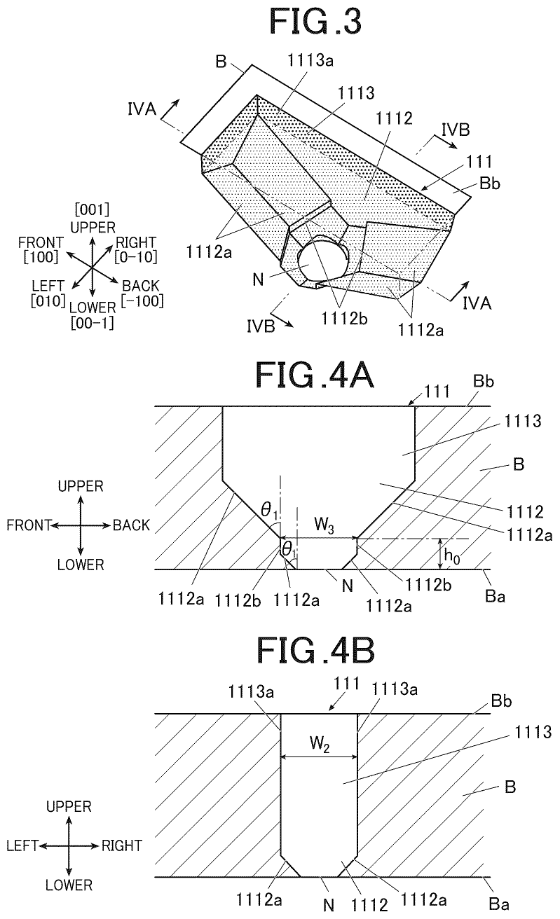

In the nozzle plate 110, a substrate B (see FIG. 3) is provided with nozzle channels 111 (see FIG. 3), which are holes penetrating in the upper-lower direction, so as to form lines in the left-right direction.

The nozzle openings N, which are openings of the nozzle channels 111, are provided on the lower surface side of the nozzle plate 110. That is, the lower surface of the nozzle plate 110 serves as an ejection surface (first surface) Ba of the inkjet head 10. Ink is ejected from the nozzle openings N substantially perpendicularly to the ejection surface Ba.

Details of the nozzle plate 110 and the nozzle channels 111 will be described later.

### {Channel Plate}

The channel plate 120 is a rectangular plate member whose shape as viewed in the upper-lower direction is substantially the same as that of the nozzle plate 110.

Through channels 121 and individual discharge channels 122 are provided in the channel plate 120.

The through channels 121 are channels that communicate with the nozzle channels 111. Furthermore, the individual discharge channels 122 are flow paths that branch from the through channels 121.

An attachment surface (second surface) Bb (see FIG. 3), which is a surface opposed to the ejection surface Ba of the nozzle plate 110, is attached (fixed) to a lower surface of the channel plate 120 with an adhesive. In addition, the lower surface of the piezoelectric plate 130 is attached (fixed) to the upper surface of the channel plate 120 with an adhesive.

The channel plate 120 is formed of, for example, a silicon substrate.

### {Piezoelectric Plate}

The piezoelectric plate 130 is a plate-shaped member having a substantially quadrangular shape which is substantially the same as the shape of the nozzle plate 110 when viewed in the upper-lower direction.

The piezoelectric plate 130 is provided with pressure chambers 131, a common discharge channel 132, and a vertical discharge channel 133.

The pressure chambers 131 communicate with the through channels 121. In addition, the common discharge channel 132 communicates with the individual discharge channels 122. Furthermore, the vertical discharge channel 133 communicates with the common discharge channel 132.

The material of the piezoelectric plate 130 is a ceramic piezoelectric material (a member that deforms in response to application of a voltage). Examples of such a piezoelectric material include lead zirconate titanate (PZT), lithium niobate, barium titanate, lead titanate, and lead metaniobate.

### {Wiring Plate}

The wiring plate 140 is a flat plate-shaped substrate having an area larger than an area of the piezoelectric plate 130.

The wiring plate 140 is provided with ink supply channels 141 and a discharge hole 142.

The ink supply channels 141 communicate with ink chambers (not illustrated) via first openings 1411 that are openings on the upper surface side. Furthermore, the ink supply channels 141 communicate with the pressure chambers 131 via the second openings 1412 on the lower surface side. Furthermore, the discharge hole 142 communicates with the vertical discharge channel 133.

The lower surface of the wiring plate 140 is attached to the upper surface of the piezoelectric plate 130 with an adhesive.

On a surface of the wiring plate 140 to be attached to the piezoelectric plate 130, a plurality of wirings to be connected to electrodes of ink channels to be described later, respectively, are provided. The FPC 200 is connected to the end of the wiring plate 140 where the wiring is provided, for example, via an anisotropic conductive film (ACF).

Drive signals output from a drive circuit (not illustrated) are supplied to the electrodes of the ink channels via wires 210 on the FPC 200 and the wires of the wiring plate 140.

As the wiring plate 140, for example, a substrate of glass, ceramic, silicon, plastic, or the like is used.

### (Ink Channels)

In a state where the channel plate 120, the piezoelectric plate 130, and the wiring plate 140 are bonded together, the through channels 121, the pressure chambers 131, and the ink supply channels 141 are respectively connected to constitute ink channels.

The ink channels are provided at positions overlapping the nozzle channels 111 when viewed from the upper-lower direction. And the ink channels communicate with the nozzle channels 111. In this way, the ink channels and the nozzle channels 111 each constitute an ink flow path.

An electrode (not illustrated) is formed on the inner wall surface of the ink channel. In accordance with the potential difference between the drive signals applied to the electrodes of the adjacent ink channels, a portion of the wall surface between the ink channels, which is made of the piezoelectric material of the piezoelectric plate 130, is displaced. The wall surface repeats shear-mode type displacement, thereby varying the pressure of the ink in the ink channel. Then, the volume of the pressure chamber 131 changes according to the fluctuation of the pressure, and the ink in the ink channel is ejected from the nozzle opening N. That is, the inkjet head 10 according to the present embodiment performs shear-mode ink ejection.

### (Ink Discharge Channels)

In addition, the individual discharge channels 122, the common discharge channel 132, the vertical discharge channel 133, and the discharge hole 142 constitute an ink discharge channel.

Some of ink supplied from the ink chamber to the ink channels is discharged to the outside of the inkjet head 10 via the ink discharge channel. Thus, air bubbles and foreign matters in the ink channels can be discharged to the outside of the inkjet head 10 together with the ink.

In the inkjet head 10 according to the present invention, the channel plate 120 is not an essential component. That is, a configuration may be adopted in which the nozzle plate 110 and the piezoelectric plate 130 are directly attached together.

The nozzle plate 110 in which only one row of the nozzle openings N arranged in the left-right direction is provided is shown in FIG. 2, but the invention is not limited thereto. That is, a plurality of rows of the nozzle openings N may be provided in the front-back direction.

### First Embodiment

### [Nozzle Channels]

FIG. 3 is an enlarged perspective view showing one nozzle channel 111 in the nozzle plate 110 according to the first embodiment. FIG. 4A is a cross-sectional view taken along a line IVA-IVA in FIG. 3, which is a straight line in a front-back direction passing through the center of the nozzle opening N. FIG. 4B is a cross-sectional view taken along a line IVB-IVB in FIG. 3, which is a straight line in a right-left direction passing through the center of the nozzle opening N.

### <Substrate>

The substrate B is, for example, a plate member made of single-crystal silicon (Si) having a thickness of about 100 μm to 725 μm. When a single crystal silicon substrate is used as the base material of the nozzle plate 110, the nozzle channel 111 can be processed with high precision in the manufacturing process. Therefore, it is possible to form the nozzle channels 111 with little positional error on and little shape variation.

The substrate B is not limited to single crystal silicon. Nickel (Ni), steel use stainless (SUS), or the like may be used.

In the following description, single crystal silicon is used as the substrate B. Furthermore, a (00-1) plane of the single crystal silicon is defined as the ejection surface Ba, and a (001) plane is defined as the attachment surface Bb.

Therefore, as shown in FIG. 3, hereinafter, a [001] direction is the same as the “upper” direction, and a [00-1] direction is the same as the “lower” direction. Further, a [100] direction is the same as the “front” direction, and a [−100] direction is the same as the “back” direction. Further, a [010] direction is the same as the “left” direction, and a [0-10] direction is the same as the “right” direction.

### (Nozzle Channel)

The nozzle channels 111 are holes that penetrate from the ejection surface Ba to the attachment surface Bb.

The nozzle channels 111 each include the nozzle opening N, a nozzle tapered part 1112, and a straight communication part 1113 from the ejection surface Ba toward the attachment surface Bb.

### {Nozzle Opening}

The nozzle opening N is a circular, elliptical, or polygonal hole that is provided in the ejection surface Ba and from which droplets are ejected. The nozzle opening N communicates with an end of the nozzle tapered part 1112 on the ejection surface Ba side.

For example, when the shape of the nozzle opening N is a circle, the diameter of the nozzle opening N is about 15 μm to 45 μm.

### {Nozzle Tapered Part}

The nozzle tapered part 1112 includes a tapered face 1112a having a substantially constant angle at which the channel area gradually increases from the ejection surface Ba toward the attachment surface Bb. The tapered face 1112a is a surface inclined from the end in the longitudinal direction of the nozzle tapered part 1112 toward the center of the nozzle opening N.

In a case where the nozzle channel 111 is formed by performing anisotropic wet etching on single crystal silicon from the {100} plane, the tapered face 1112a has four {111} planes.

Note that the “channel area” in the present invention refers to a cross-sectional area in a direction orthogonal to the upper-lower direction that is an ink ejection direction.

A taper angle θ₁, which is an angle formed by the tapered face 1112a of the nozzle tapered part 1112 shown in FIG. 4A and an axis parallel to the nozzle central axis, is 15 degrees or more.

When the substrate B is formed of single crystal silicon, the taper angle θ₁ is 45° due to the etching characteristics of Si.

The nozzle tapered part 1112 can stabilize the meniscus shape and ink ejection even when the meniscus of ink has retracted to the depth of the nozzle channel 111 due to high-speed driving.

### {Riser Face}

In addition, at least one pair of riser parts is provided in the nozzle tapered part 1112. The riser faces 1112b are vertical surfaces or inclined surfaces which form a step with the tapered faces 1112a of the nozzle tapered part 1112 with the nozzle opening N interposed therebetween.

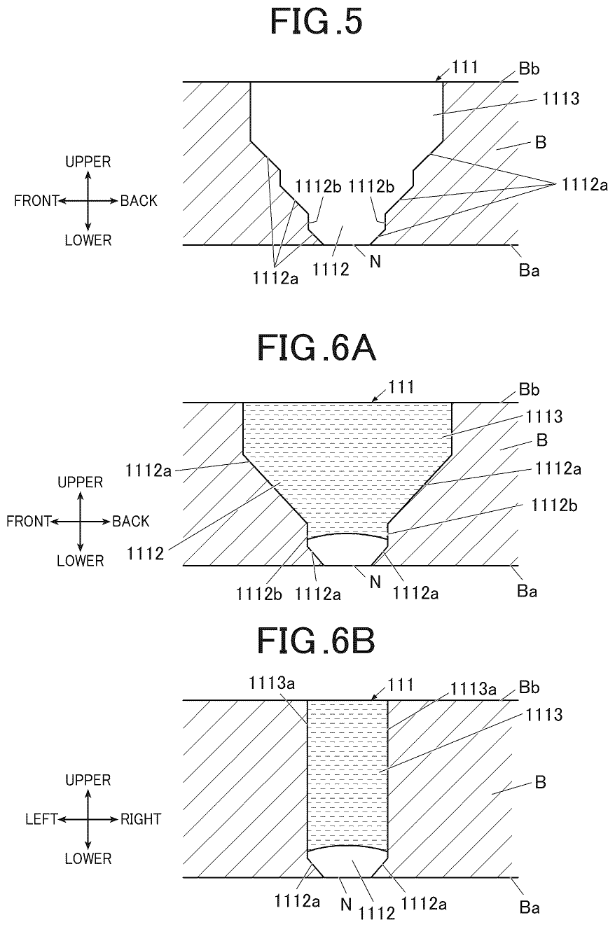

As shown in FIG. 5, a plurality of riser parts may be provided in the nozzle tapered part 1112. However, in the present invention, only the surface positioned closest to the nozzle opening N among the surfaces forming the step in the nozzle tapered part 1112 is referred to as the “riser face 1112b”.

The riser face 1112b in the nozzle tapered part 1112 suppresses spreading of menisci in the front-back direction as shown in FIGS. 6A and 6B, even if ink is drawn into the nozzle channel 111. Therefore, the stability of the meniscus shape is enhanced, allowing the nozzle channel 111 to have excellent ejection characteristics.

In a case where the riser faces 1112b are inclined surfaces, an angle formed by the inclined surface and the parallel to the nozzle central axis is only required to be smaller than the taper angle θ₁.

Further, the distance h₀ from the nozzle opening N to the end of the riser face 1112b on the side of the attachment surface Bb shown in FIG. 4A is only required to be larger than the maximum height at which a meniscus may rise. Preferably 20 μm≤h₀≤60, to be specific.

This is because the ink is rarely drawn in by greater than 20 μm. In addition, if h₀>60 μm, the nozzle channel 111 cannot secure a sufficient volume.

In addition, a width of the pair of riser faces 1112b in the front-back direction (an interval between the riser faces 1112b) is W3 (refer to FIG. 4A). A distance of the surfaces forming the long sides of the straight communication part 1113 in the right-left direction (refer to FIG. 4B), in a cross section in the longitudinal direction passing through the center of the nozzle opening N is W2. Here, it is preferable that a relation between a width W₃ is W₂≈W₃.

When the riser faces 1112b are formed in such a relation, the nozzle channel 111 has excellent ejection characteristics. That is because a space having a substantially square shape in top plan view, which is formed by the riser faces 1112b and the surfaces parallel to the surfaces forming the long sides of the straight communication parts 1113 among the surfaces of the nozzle tapered parts 1112, is formed in the vicinity of the nozzle opening N, having symmetry.

### {Straight Communication Part}

The straight communication part 1113 communicates with the end of the nozzle tapered part 1112 on the attachment surface Bb side, and is provided up to the attachment surface Bb.

In the straight communication part 1113, a pair of surfaces 1113a facing each other are substantially parallel to each other. Furthermore, among the sides of the surfaces forming the straight communication part 1113 that intersect with the attachment surface Bb, the length in the front-back direction (the first direction) along the pair of opposing surfaces 1113a is longer than the length in the right-left direction (the second direction). That is, as shown in FIG. 3, the shape of the opening of the nozzle channel 111 on the attachment surface Bb is an elongated shape.

This configuration makes it possible to arrange the nozzle openings N at a narrow pitch of the short side length of the elongated shape while securing the volume of the nozzle channel 111. Therefore, it is possible to increase the density of the nozzle opening N in the nozzle plate 110.

The shape of the opening of the nozzle channel 111 in the attachment surface Bb is not limited to a rectangular shape. The shape of the opening of the nozzle channel 111 on the attachment surface Bb is not particularly limited as long as the shape is an elongated shape in which the length in the front-back direction is longer than the length in the left-right direction, such as a hexagonal shape or an elliptical shape. However, for the nozzle plate 110 in which the opening of the nozzle channel 111 on the attachment surface Bb side is expanded by performing Step 3 (removal processing) described later, the opening necessarily has a rectangular shape.

### [Method of Manufacturing Nozzle Plate According to First Embodiment]

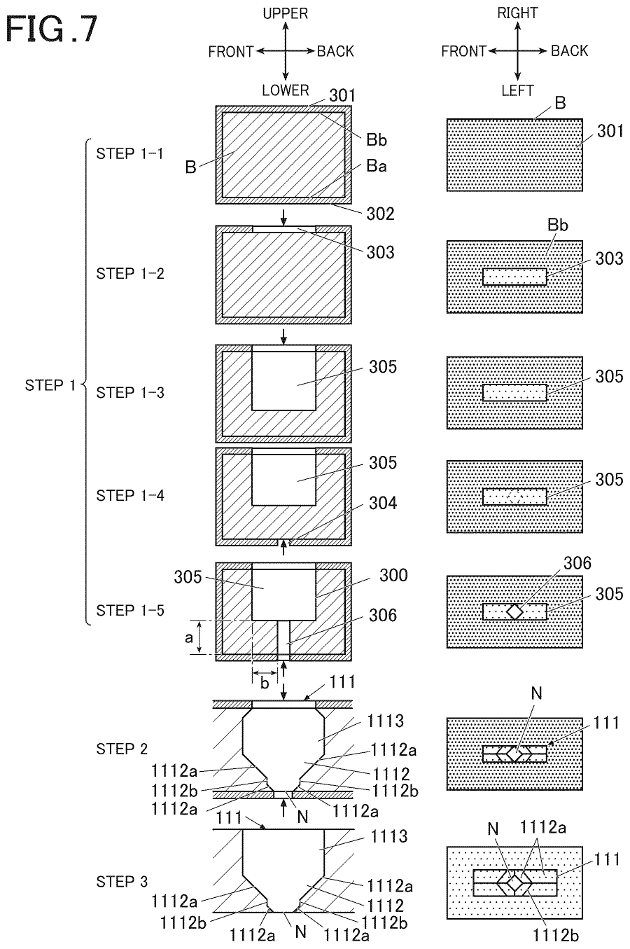

A method of manufacturing such a nozzle plate 110 will be described with reference to FIG. 7.

In the following description, single crystal silicon is used as the substrate B.

The method of manufacturing the nozzle plate 110 includes, for example, Steps 1 to 3 shown in FIG. 7.

In Step 1, an intermediate structure 300 having an opening hole 305 and a nozzle hole 306 which will be described later is formed. Furthermore, in Step 2, anisotropic wet etching is performed on the intermediate structure 300 formed in Step 1 to form the nozzle channel 111. Furthermore, in Step 3, removal processing is appropriately performed on the nozzle plate 110 formed in Step 2.

### {Step 1: Intermediate Structure Forming Step}

### (Step 1-1)

As shown in FIG. 7, Step 1 is further subdivided into a plurality of steps.

First, as Step 1-1, a mask layer is formed on a surface of single crystal silicon whose crystal orientation of the surface is a {100} plane.

The mask layer may be any layer that stops the progress of etching in Step 2 and that is not removed by etching. Hereinafter, the mask layer formed on the attachment surface Bb is referred to as a front surface mask layer 301, and the mask layer formed on the ejection surface Ba is referred to as a back surface mask layer 302.

### (Step 1-2)

Next, as Step 1-2, an elongated opening pattern 303 to be an opening of the nozzle channel 111 on the attachment surface Bb side is formed on the (001) plane of the single crystal silicon.

Specifically, a resist layer is formed on the front surface mask layer 301 of the (001) plane by a well-known photolithography technique. After formation of the resist layer, exposure with an aligner or the like is performed to form a resist pattern. After formation of the resist pattern, using the resist pattern as a mask, dry etching is performed with, for example, a reactive ion etching (RIE) apparatus to form the opening pattern 303. After formation of the opening pattern 303, the resist pattern is removed.

In FIG. 7, the shape of the opening pattern 303 is a rectangular shape having a long side along the front-back direction, but the invention is not limited thereto. The shape of the opening pattern 303 may be, for example, a hexagonal shape, an oval shape, or a shape in which a short side of a rectangle is combined with a semicircle having a diameter equal to the width of the short side. The shape of the opening pattern 303 is to be an elongated shape in which the length in the front-back direction is longer than the length in the right-left direction.

### (Step 1-3)

Next, as Step 1-3, the single crystal silicon under the opening pattern 303 is subjected to deep digging processing by dry etching to form the opening hole 305.

### (Steps 1-4 and 1-5)

Next, as Step 1-4, the nozzle pattern 304 which becomes the nozzle opening N is formed on the (00-1) plane of the single crystal silicon. Furthermore, as Step 1-5, the single-crystal silicon under the nozzle pattern 304 is subjected to deep digging processing by dry etching, thereby forming the nozzle hole 306.

Although Steps are performed in the order of Step 1-2, Step 1-3, Step 1-4, and Step 1-5 above, the present invention is not limited thereto. It is sufficient that least Step 1-2 is performed before Step 1-3 and Step 1-4 is performed before Step 1-5.

However, in Step 1, the intermediate structure 300 is formed such that a depth a of the nozzle hole 306 in the [001] direction (the upper-lower direction) is longer than a length b from the end of the nozzle hole 306 on the attachment surface Bb side to the end of the opening hole 305 in the [100] direction (the front-back direction).

Hereinafter, the aforementioned condition is referred to as “Condition 1”.

### {Step 2: Anisotropic Wet Etching Step}

Next, as Step 2, anisotropic wet etching is performed from both the ejection surface Ba and the attachment surface Bb of the intermediate structure 300. The opening hole 305 provided in Step 1-3 and the nozzle hole 306 provided in Step 1-5 are thereby enlarged to form the nozzle channel 111. At this time, if Condition 1 is satisfied, the tapered face formed from the nozzle hole 306 and the tapered face formed from the opening hole 305 do not match. As a result, the riser face 1112b is formed in the nozzle tapered part 1112.

### {Step 3: Removal Processing Step}

Next, as Step 3, removal processing such as etching, grinding, and polishing is performed. Specifically, for example, the diameter of the opening of the nozzle channel 111 on the attachment surface Bb side is enlarged so that the straight communication part 1113 becomes a substantially vertical hole. Alternatively, the thickness of the nozzle plate 110 is adjusted to have a desired dimension. Alternatively, the mask layer is removed.

It should be noted that Step 3 is not an essential step in manufacturing the nozzle plate 110 in the first embodiment and may be appropriately performed as necessary.

### Second Embodiment

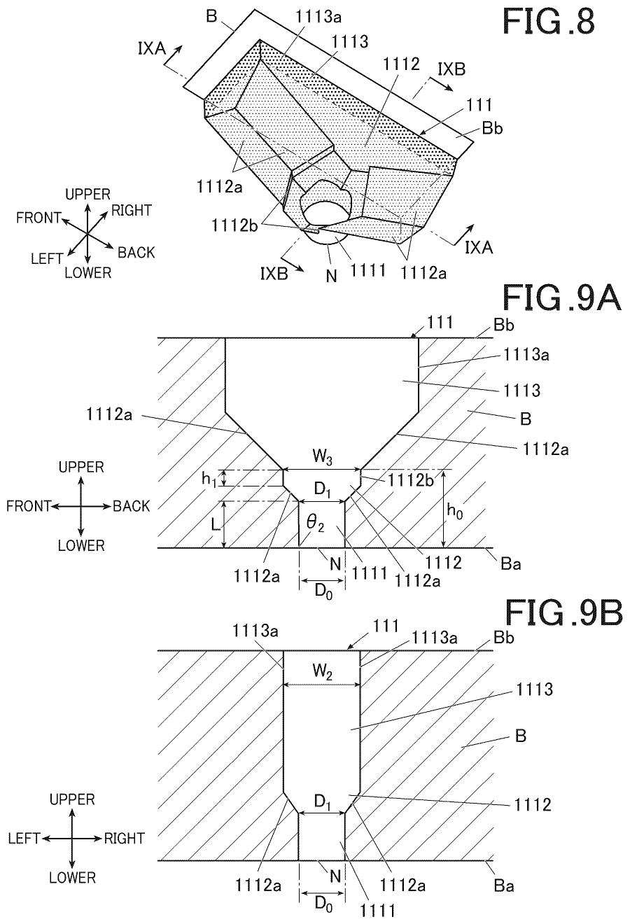

The nozzle plate 110 according to the second embodiment will be described with reference to FIGS. 8 and 9.

FIG. 8 is an enlarged perspective view showing one nozzle channel 111 in the nozzle plate 110 according to the second embodiment. FIG. 9A is a cross-sectional view taken along a line IXA-IXA in FIG. 8, which is a straight line in a front-back direction passing through the center of a nozzle opening N. FIG. 9B is a cross-sectional view taken along a line IXB-IXB in FIG. 8, which is a straight line in the right-left direction passing through the center of a nozzle opening N.

A configuration similar to that of the nozzle plate 110 according to the first embodiment is denoted by the same reference sign, and a detailed description thereof is omitted.

The nozzle plate 110 according to the second embodiment is different from the nozzle plate 110 according to the first embodiment in that the nozzle channel 111 includes a nozzle straight part 1111.

### {Nozzle Straight Part}

The nozzle straight part 1111 is formed so as to be continuous with the end of the nozzle tapered part 1112 on the ejection surface Ba side and the nozzle opening N.

The channel area of the nozzle straight part 1111 is always constant from the attachment surface Bb side to the ejection surface Ba side. That is, the angle θ₂ formed between the surface forming the nozzle straight part 1111 and an axis parallel to the nozzle central axis is 0°.

The angle θ₂ formed between the nozzle straight part 1111 and an axis parallel to the nozzle central axis is not limited to 0°. The nozzle straight part 1111 may have a taper such that the channel area becomes gradually wider as it extends from the ejection surface Ba toward the attachment surface Bb side.

To be more specific, the angle θ₂ formed by the plane constituting the nozzle straight part 1111 and the axis parallel to the nozzle central axis may be substantially constant at any position, and is only required to be 0°≤θ₂<15°. Further, as shown in FIGS. 9A and 9B, when the diameter of the end of the nozzle straight part 1111 on the attachment surface Bb side is D₁ and the diameter of the nozzle opening N, that is, the diameter of the end of the nozzle straight part 1111 on the ejection surface Ba side is D₀, it is only required that D₁>D₀.

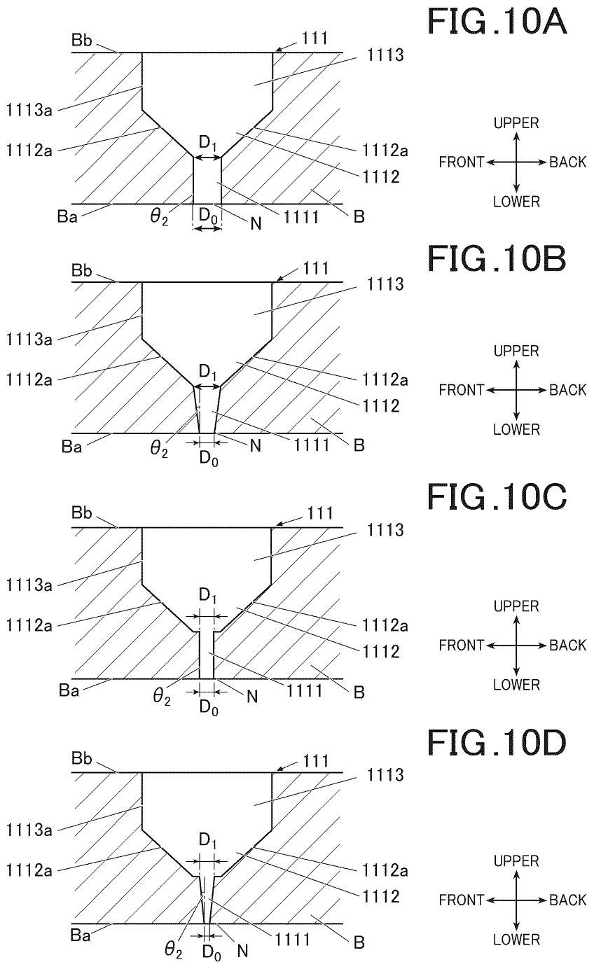

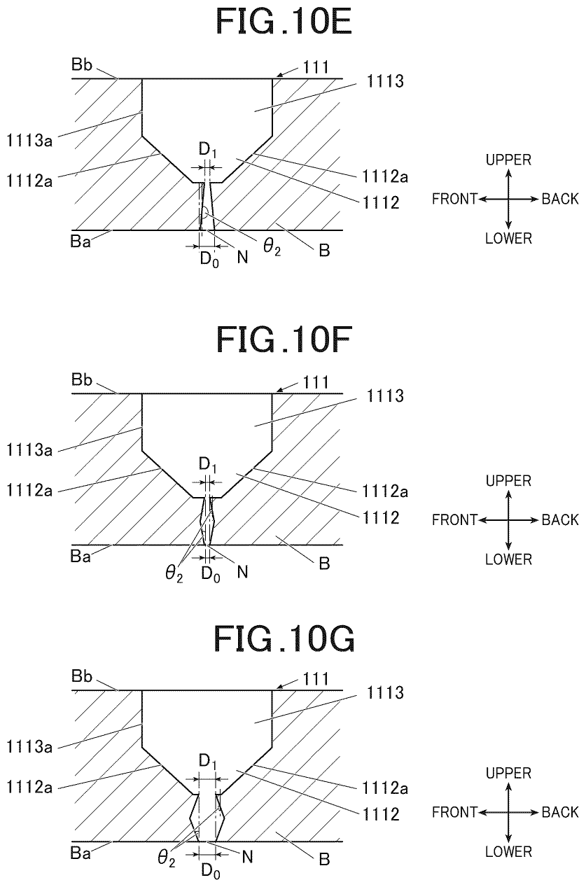

That is, in the nozzle channels 111 shown in FIGS. 10A to 10G, the lower part of the nozzle tapered parts 1112 in FIGS. 10A to 10D are the “nozzle straight part 1111” which satisfies all of the above conditions.

On the other hand, the lower parts of the nozzle tapered parts 1112 in FIGS. 10E to 10G do not correspond to the “nozzle straight part 1111” according to the present invention. In particular, FIG. 10E does not satisfy the D₁>D₀ and does not satisfy 0°≤θ₂ 15°. Further, in FIGS. 10F and 10G, D₁≥D₀, but θ₂ is not substantially constant at any place.

The riser face 1112b is not illustrated in FIGS. 10A to 10G.

Furthermore, it is desirable that a length in the upper-lower direction, which is a height L of the nozzle straight part 1111 shown in FIG. 9A, is approximately 5 μm to 50 μm. When the height of the nozzle straight part 1111 is within the above range, appropriate resistance is applied when the ink is ejected.

When the nozzle straight part 1111 is provided in the nozzle channel 111, resistance applied when ink is ejected from the nozzle opening N increases. Thus, since the vibration of the meniscus is suppressed, the meniscus shape can be made more stable.

When W₂≈W₃, the height of the riser face 1112b in the upper-lower direction, which is a height h₁, is expressed by the following Expression (3).

h₁=h₀−(W₂−D₁)/(2 tan θᵢ)−L≈h₀−(W₃−D₁)/(2 tan θ1)−L (3)

In addition, the diameter D₁ of the end of the nozzle straight part 1111 on the attachment surface Bb side, or the diameter of the end of the nozzle tapered part 1112 on the ejection surface Ba side is expressed by the following Expression (4).

D₁=D₀+2×L tan θ₂ (4)

### [Method of Manufacturing Nozzle Plate of Second Embodiment]

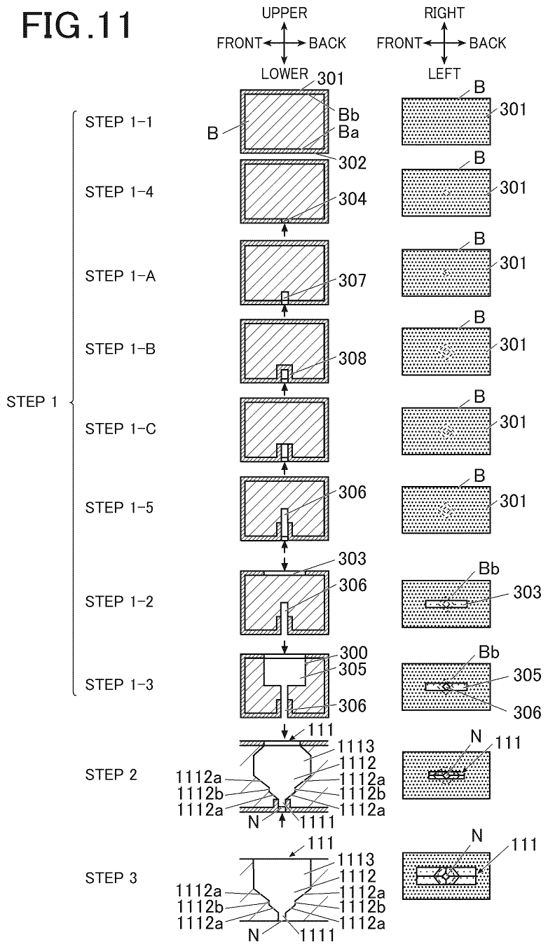

A method of manufacturing the nozzle plate 110 according to the second embodiment will be described with reference to FIG. 11.

The method of manufacturing the nozzle plate 110 according to the second embodiment is different from the method for manufacturing the nozzle plate 110 according to the first embodiment in that Steps 1-A to 1-C are performed between Steps 1-4 and 1-5.

### (Step 1-A)

After forming the mask layer in Step 1-1, the nozzle pattern 304 is formed in Step 1-4. After formation of the nozzle pattern 304, as Step 1-A, q nozzle straight hole 307 is formed by performing dry etching by the length of the planned nozzle straight part 1111.

### (Step 1-B)

Next, as Step 1-B, a nozzle mask layer 308 is formed along the inner surface of the nozzle straight hole 307. The method of forming the nozzle mask layer 308 is the same as the method of forming the mask layer.

### (Step 1-C)

Thereafter, as Step 1-C, the nozzle mask layer 308 formed at the bottom of the nozzle straight hole 307 is removed by dry etching, so that the nozzle mask layer 308 is left only at the side surface part of the nozzle straight hole 307.

### (Steps 1-5, 1-2, and 1-3)

After Step 1-C, as Step 1-5, the substrate B is dry-etched, and the nozzle straight hole 307 is further deeply dug, thereby forming the nozzle hole 306. Next, the opening hole 305 is provided by Steps 1-2 and 1-3.

### (Steps 2 and 3)

Next, anisotropic wet etching is performed as Step 2. However, since the nozzle straight hole 307 is protected by the nozzle mask layer 308, the progress of etching is suppressed, and the nozzle straight hole 307 remains as the nozzle straight part 1111. As a result, the nozzle channel 111 including the nozzle straight part 1111 is formed.

After Step 2, Step 3 is appropriately performed as necessary.

### Modification Example

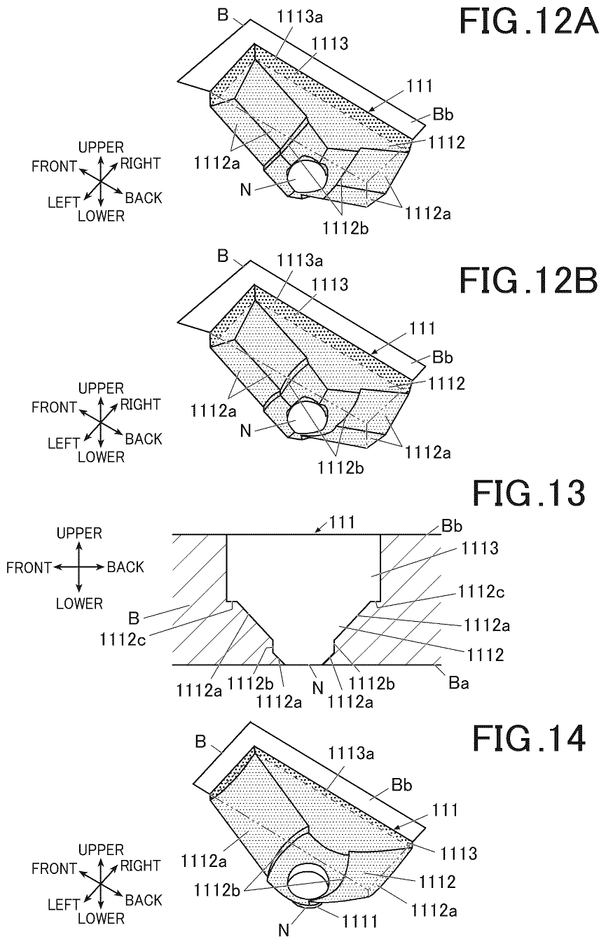

The riser face 1112b is not limited to a two-surface shape as shown in FIGS. 3 and 8, but may be a one-surface shape having a linear shape in top view as shown in FIG. 12A. Further, the shape may be a curved surface that is convex in the forward direction as shown in FIG. 12B.

In addition, in FIG. 3, etc., the nozzle tapered part 1112 and the straight communication part 1113 are continuous in the nozzle channel 111, but the invention is not limited thereto. For example, as shown in FIG. 13, the nozzle channel 111 may include a planar part 1112c that is substantially parallel to the attachment surface Bb and the ejection surface Ba between the nozzle tapered part 1112 and the straight communication part 1113.

In FIG. 3, etc., the nozzle tapered part 1112 includes four tapered faces 1112a, but the invention is not limited thereto.

For example, as shown in FIG. 14, the nozzle channel 111 may have an elliptic funnel shape and include a curved tapered face.

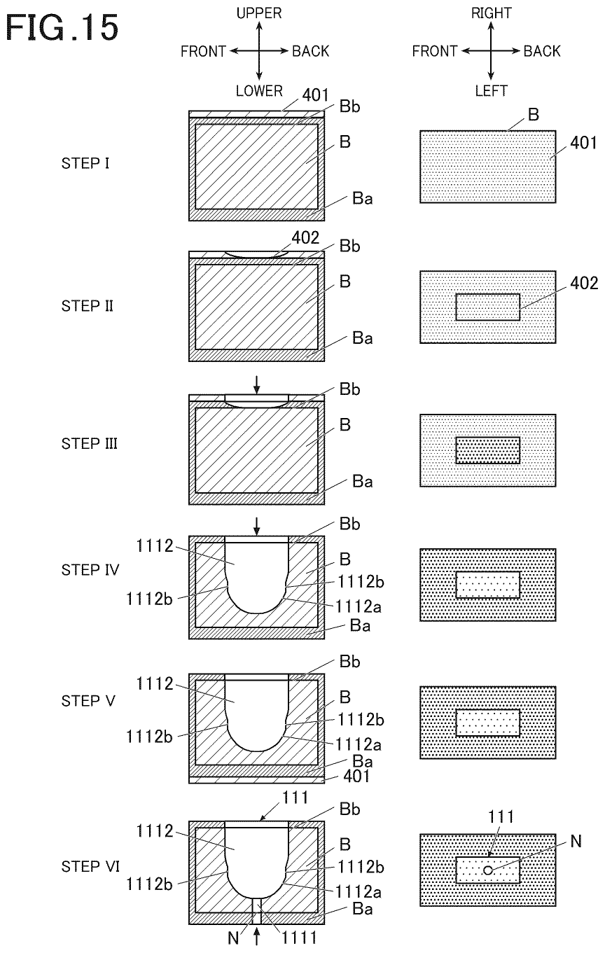

A method of manufacturing the nozzle plate 110 including such a nozzle channel 111 will be described with reference to FIG. 15.

### [Method of Manufacturing Nozzle Plate According to Other Examples]

### (Step I)

First, as Step I, a resist layer 401 is formed on the attachment surface Bb of the silicon wafer having quartz layers (mask layers) formed on the attachment surface Bb and the ejection surface Ba.

### (Step II)

Next, as Step II, a gray-tone mask is pressed against the resist layer 401, and then the resist layer 111 is exposed to ultraviolet (UV). Thereafter, the exposed part of the resist layer 401 is removed by immersion in a developing solution.

Since the gray-tone mask has a distribution in transmittance of light, a resist pattern having a gradient is formed in which the thickness of the resist layer 401 is distributed in accordance with the distribution. At this time, the riser face 1112b is provided in the nozzle tapered part 1112 in accordance with the design of the gray-tone mask.

### (Step III)

Next, as Step III, the quartz layer is dry-etched using the resist pattern as a mask. At this time, the thickness distribution of the photoresist 402 is transferred to the quartz layer.

### (Step IV)

Furthermore, as Step IV, the single crystal silicon is dry-etched with the quartz layer as a mask. At this time, the thickness distribution is also transferred to the single crystal silicon in accordance with the thickness distribution of the quartz layer.

Although depending on the etching conditions, the ratio of the thickness distribution of the quartz layer to the thickness distribution of the single crystal silicon is usually about 1:50 to 1:100.

### (Step V)

After dry etching by a predetermined etching amount, as Step V, the resist layer 401 is formed on the ejection surface Ba of the silicon wafer and is exposed to light, to form a resist pattern. Then, as Step VI, the nozzle opening N and the nozzle straight part 1111 are formed by performing dry etching to communicate with the hole provided in Step IV.

### EXAMPLES

Next, with respect to Examples and Comparative Examples of the present invention, the results of evaluating preferred configurations will be described. Hereinafter, the present invention will be specifically described with reference to Examples, but the present invention is not limited thereto.

### [Sample Preparation]

A nozzle plate 110 made of single crystal silicon having 1280 nozzle channels 111 in each of the following Examples and Comparative Examples was manufactured. Next, a piezoelectric plate having an ink channel in which the shape of the opening on the attachment surface is the same as the shape of the opening part on the attachment surface Bb side of the nozzle plate 110 was bonded to form an inkjet head 10. Then, the inkjet head 10 was mounted on the inkjet recording device 1.

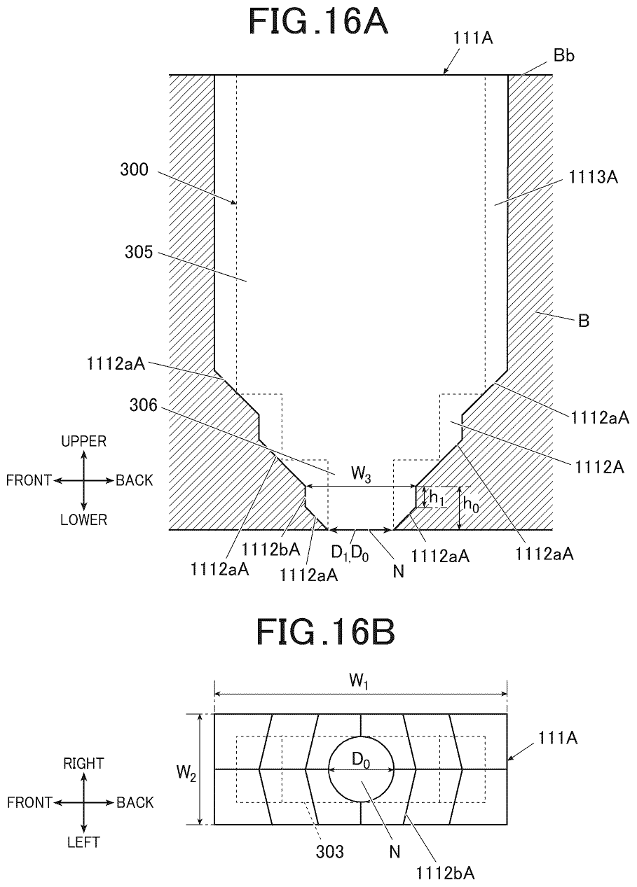

FIGS. 16A to 23B each show one nozzle channel 111 in the nozzle plate 110 according to each of the Examples and the Comparative Examples. In each of the drawings, a dotted line portion indicates the intermediate structure 300 formed in Step 1. In addition, a solid line portion indicates the nozzle channel 111 in which an opening on the attachment surface Bb side is formed in a rectangular shape by performing anisotropic wet etching on the intermediate structure 300 in Step 2 and performing removal processing such that the straight communication part 1113 becomes substantially vertical in Step 3.

Hereinafter, the length of the long side of the opening on the attachment surface Bb side of the nozzle channel 111 after Step 3 is defined as W₁.

### Example 1

As shown in FIGS. 16A and 16B, the nozzle channel 111A of Example 1 included the nozzle tapered part 1112A, the riser face 1112bA, and the straight communication part 1113A.

As specific dimensions, W₁=130 μm and W₂=W₃=50 μm. In addition, h₀=20 μm, h₁=10 μm, and D₀=D₁=30 μm. Furthermore, as shown in the FIG. 16A, a riser part was also provided above the riser face 1112bA in the tapered face 1112aA.

Further, as shown in FIG. 16B, the opening pattern 303 has a rectangular shape. The shape of the nozzle opening N is circular.

### Example 2

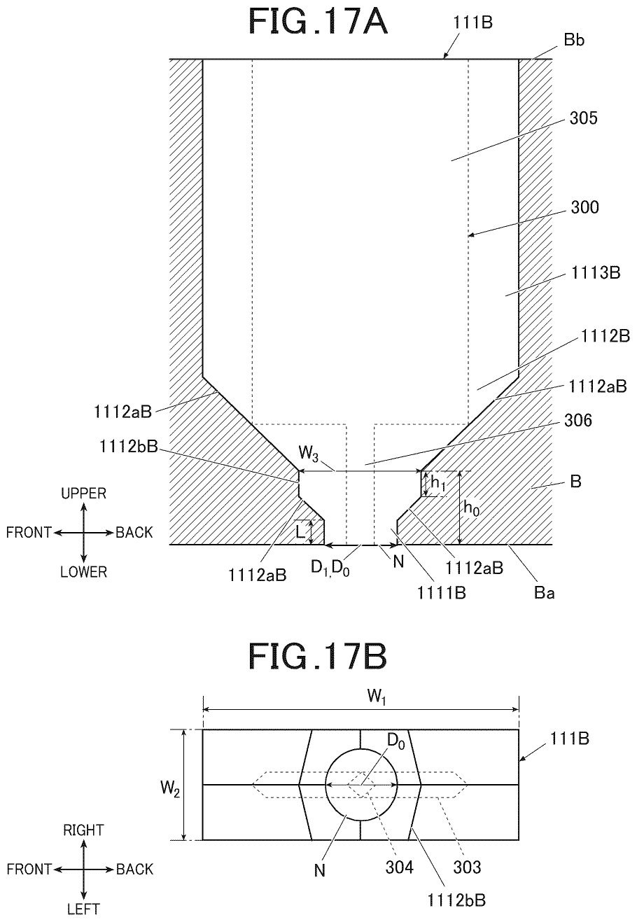

As shown in FIGS. 17A and 17B, the nozzle channel 111B of Example 2 included the nozzle straight part 1111B, the nozzle tapered part 1112B, the riser face 1112bB, and the straight communication part 1113B.

As specific dimensions, W₁=130 μm and W₂=W₃=50 μm. In addition, h₀=30 μm, h₁=10 μm, and D₀=D₁=30 μm.

As shown in FIGS. 17A and 17B, in the present example, the diamond-shaped nozzle pattern 304 having a diameter of 10 μm was formed in Step 1-4. And in the present example, the nozzle opening N was expanded to have a circular shape having a diameter of 30 μm in Step 3. Therefore, a nozzle straight part 1111B having a length L of 10 μm was formed.

Further, as shown in FIG. 17B, the opening pattern 303 had a hexagonal shape.

### Example 3

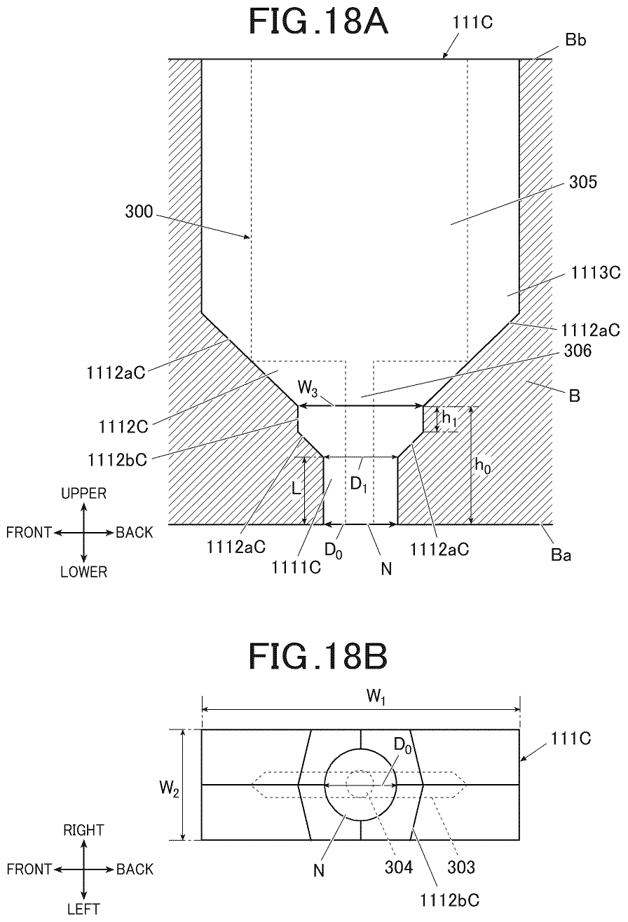

As shown in FIGS. 18A and 18B, the nozzle channel 111C of Example 3 included the nozzle straight part 1111C, the nozzle tapered part 1112C, the riser face 1112bC, and the straight communication part 1113C.

As specific dimensions, W₁=130 μm and W₂=W₃=50 μm. Further, h₀=50 μm and h₁=10 μm. In addition, D₀=D₁=30 μm and L=30 μm.

As shown in FIGS. 18A and 18B, in the present example, the circular shaped nozzle pattern 304 having a diameter of 10 μm was formed in Step 1-4, and the nozzle opening N was expanded to have a circular shape having a diameter of 30 μm in Step 3.

Further, as shown in FIG. 18B, the opening pattern 303 had a hexagonal shape.

### Example 4

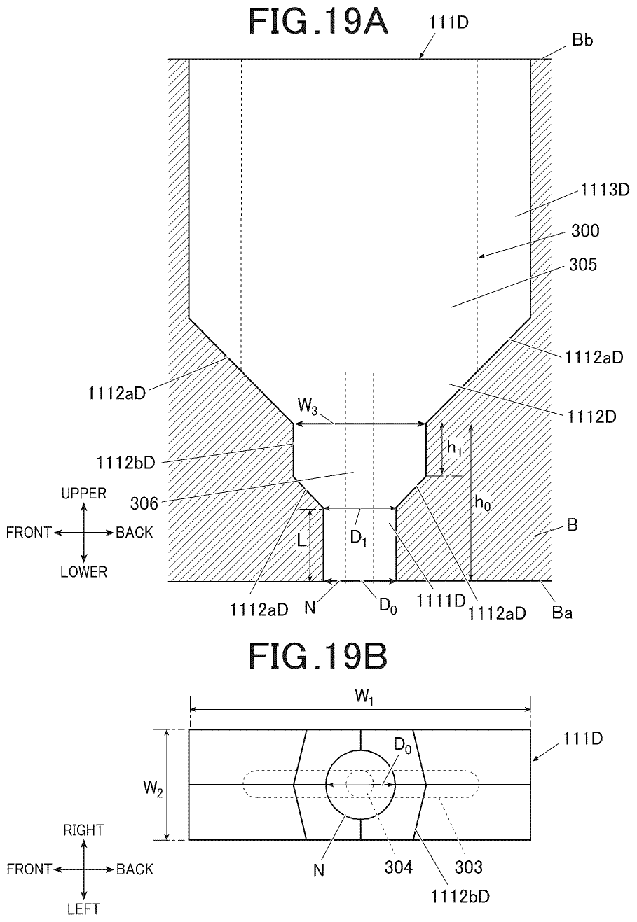

As shown in FIGS. 19A and 19B, the nozzle channel 111D of Example 4 included the nozzle straight part 1111D, the nozzle tapered part 1112D, the riser face 1112bD, and the straight communication part 1113D.

As specific dimensions, W₁=130 μm and W₂=W₃=50 μm. Further, h₀=60 μm and h₁=20 μm. In addition, D₀=D₁=30 μm and L=30 μm.

As shown in FIGS. 19A and 19B, in the present example, the circular shaped nozzle pattern 304 having a diameter of 10 μm was formed in Step 1-4. And in the present example, the nozzle opening N was expanded to have a circular shape having a diameter of 30 μm in Step 3.

Further, as shown in FIG. 19B, the shape of the opening pattern 303 was a combination of a short side of a rectangle and a semicircle having the same width as the short side.

### Example 5

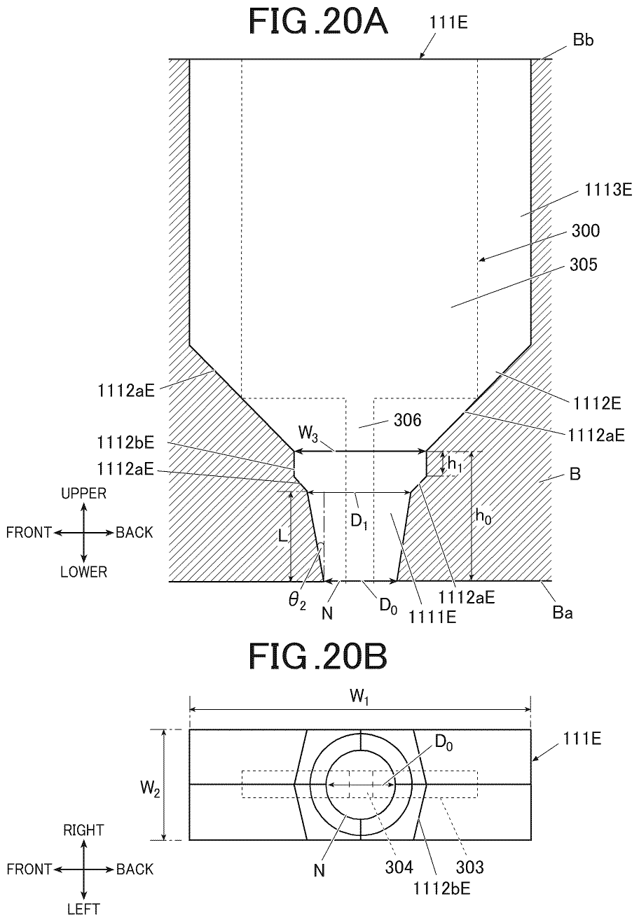

As shown in FIGS. 20A and 20B, the nozzle channel 111E of Example 5 included the nozzle straight part 1111E, the nozzle tapered part 1112E, the riser face 1112bE, and the straight communication part 1113E.

As specific dimensions, W₁=130 μm and W₂=W₃=50 μm. Further, h₀=50 μm and h₁=10 μm.

As shown in FIGS. 20A and 20B, in the present example, the square-shaped nozzle pattern 304 having a diameter of 10 μm was formed in Step 1-4. And in the present example, the nozzle opening N was expanded to have a circular shape having a diameter of 30 μm in Step 3.

Further, as shown in FIG. 20A, in this example, the nozzle straight part 1111E was formed into a tapered shape in Step 3 so as to satisfy θ₂=8°. Therefore, D₁=40 μm, D₀=30 μm, and L=35 μm.

As shown in FIG. 20B, the opening pattern 303 had a rectangular shape.

### Example 6

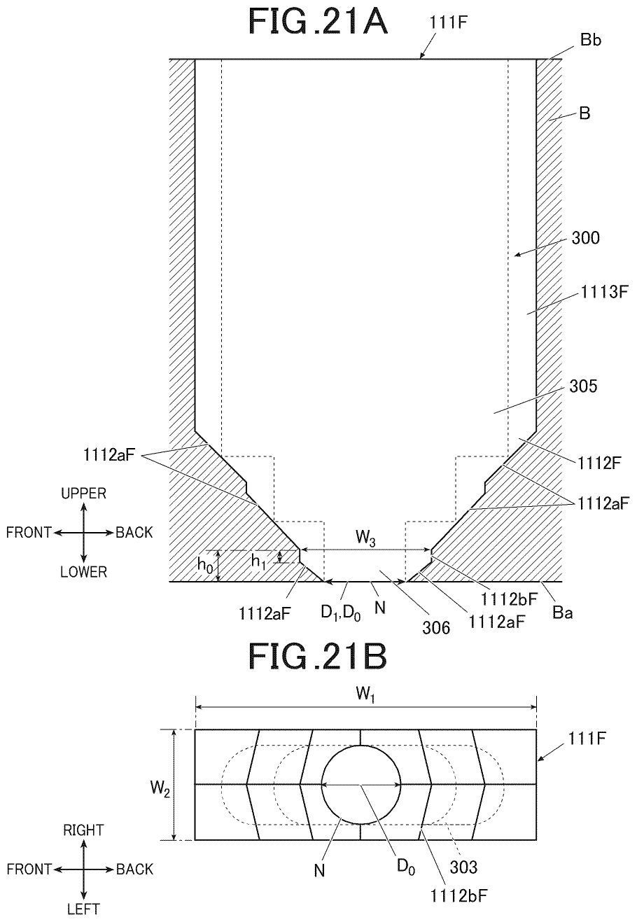

As shown in FIGS. 21A and 21B, the nozzle channel 111F of Example 6 included the nozzle tapered part 1112F, the riser face 1112bF, and the straight communication part 1113F.

As specific dimensions, W₁=130 μm and W₂=W₃=50 μm. And, h₀=15 μm, h₁=5 μm, and D₀=D₁=30 μm. Furthermore, as shown in the FIG. 21A, a riser part was also provided above the riser face 1112bF in the tapered face 1112aF.

Further, as shown in FIG. 21B, the shape of the opening pattern 303 was a combination of a short side of a rectangle and a semicircle having the same width as the short side. The shape of the nozzle opening N was circular.

### Example 7

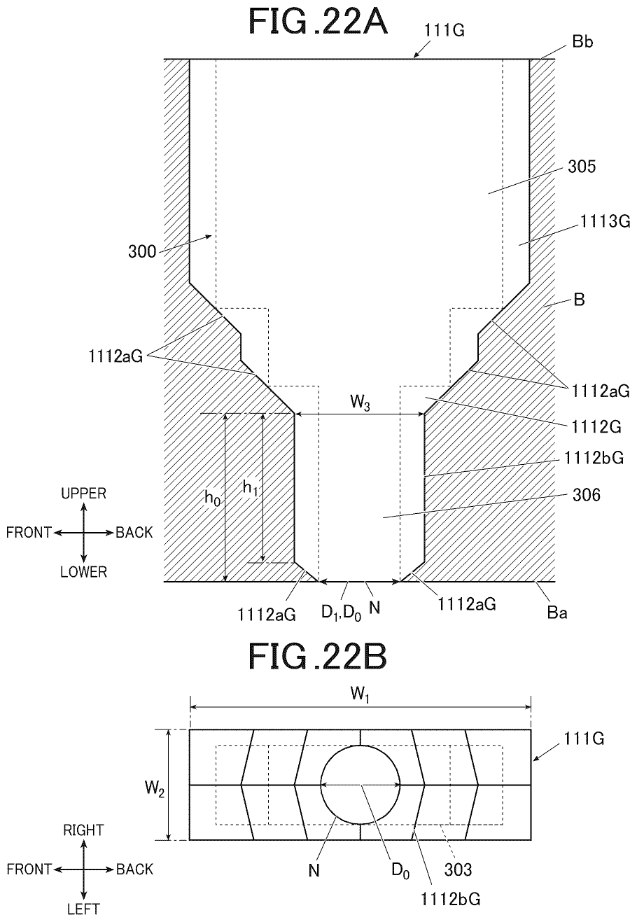

As shown in FIGS. 22A and 22B, the nozzle channel 111G of Example 7 included the nozzle tapered part 1112G, the riser face 1112bG, and the straight communication part 1113G.

As specific dimensions, W₁=130 μm and W₂=W₃=50 μm. And, h₀=65 μm, h₁=55 μm, and D₀=D₁=30 μm. Furthermore, as shown in the FIG. 22A, a riser part was also provided above the riser face 1112bG in the tapered face 1112aG.

As shown in FIG. 22B, the opening pattern 303 had a rectangular shape. The shape of the nozzle opening N was circular.

### Comparative Example 1

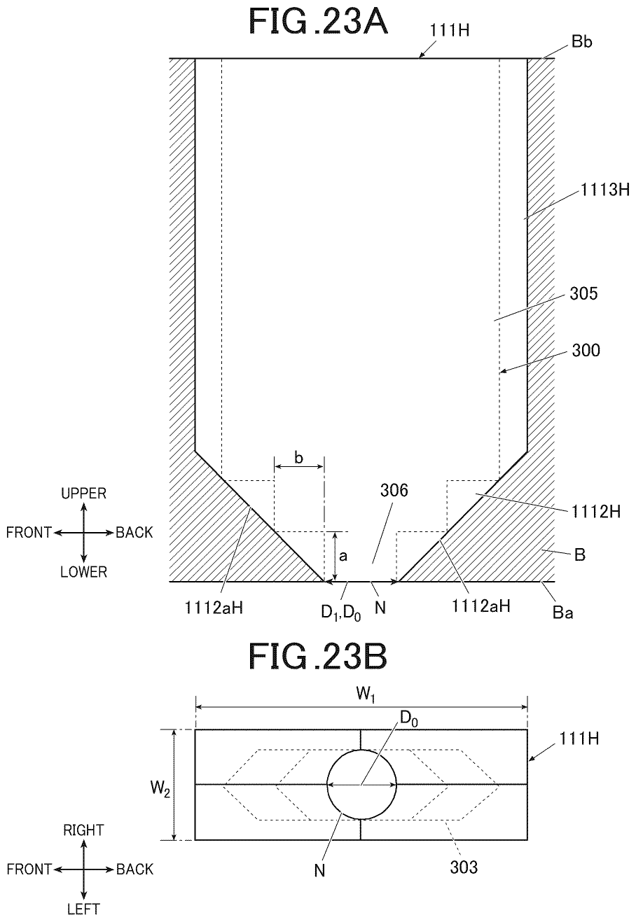

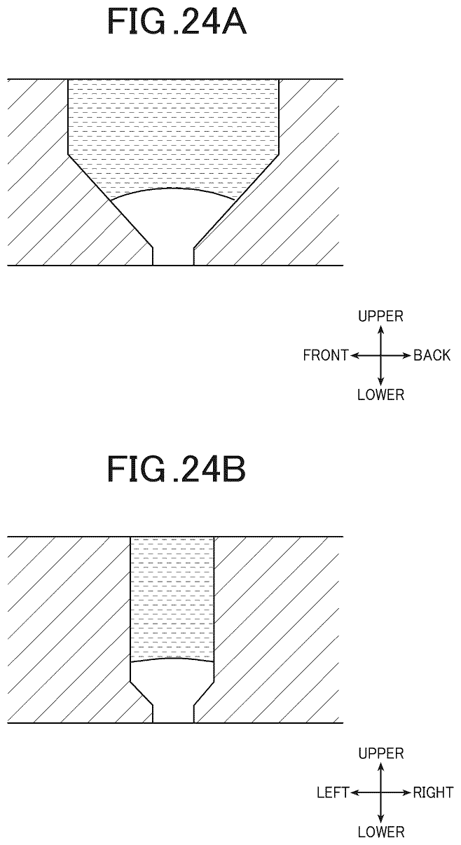

As shown in FIGS. 23A and 23B, the nozzle channel 111F of Comparative Example 1 included only the nozzle tapered part 1112H and the straight communication part 1113H. As shown in FIG. 23A, in the present comparative example, since the dimensions were adjusted so as to satisfy a=b in Step 1. Therefore, the nozzle tapered part 1112H does not include the riser face 1112b.

As specific dimensions, W₁=130 μm and W₂=50 μm. Further, D₀=D₁=30 μm.

Further, as shown in FIG. 23B, the opening pattern 303 had a hexagonal shape. The shape of the nozzle opening N was circular.

### Comparative Example 2

The nozzle channel 111 was formed by a conventionally known method.

That is, the nozzle channel 111 include the nozzle tapered part 1112 and the straight communication part 1113. However, the nozzle tapered part 1112 does not include the riser face 1112b. The opening of the nozzle channel 111 on the attachment surface Bb side has a square shape in which W₁=50 and W₂=50 μm.

The following Tests 1 and 2 were performed using the inkjet recording device 1 on which the inkjet head 10 that includes the nozzle plate 110 of each of Examples 1 to 7 and Comparative Examples 1 and 2 described above was mounted.

### [Test 1. Ejection Angle Test]

The UV ink heated to a viscosity of 8 cP was ejected at a drive voltage at which the average droplet speed was about 6 m/s. Then, within plus or minus how many degrees the ejection angle, the angle between the nozzle central axis and the ejected liquid, was evaluated for the 1280 nozzles.

### [Test 2. Maximum Speed Test]

At a drive frequency of 40 kHz, the ejection speed of the UV ink heated to a viscosity of 8 cP was increased from 5 m/s. Then, the ejection speed at which an ejection defect at the nozzle opening N occurred in 5 nozzles or more out of 100 nozzles was measured. In a case where the ejection speed is equal to or higher than 9 m/s, although an ejection defect hardly occurs even when the ejection speed is high, it is more desirable that the ejection speed is equal to or higher than 10 m/s, and still more desirable that the ejection speed is extremely equal to or higher than 11 m/s. Therefore, meniscus instability was rated as “C” for lower than 9 m/s, “B” for 9 m/s or higher and lower than 10 m/s, “A” for 10 m/s or higher and lower than 11 m/s, and “AA” for 11 m/s or more.

The results of Tests 1 and 2 are shown in Table I.

TABLE I

| | *1 | *1 | *1 | *1 | *1 | *1 | *1 | *2 | *2 |
|---|---|---|---|---|---|---|---|---|---|
| | 1 | 2 | 3 | 4 | 5 | 6 | 7 | 1 | 2 |
| W₁ (LENGTH OF LONG SIDE OF | 130 | 130 | 130 | 130 | 130 | 130 | 130 | 130 | 50 |
| OPENING OF NOZZLE CHANNEL ON | | | | | | | | | |
| ADHESION FACE SIDE) [μm] | | | | | | | | | |
| W₂ (LENGTH OF SHORT SIDE OF | 50 | 50 | 50 | 50 | 50 | 50 | 50 | 50 | 50 |
| OPENING OF NOZZLE CHANNEL ON | | | | | | | | | |
| ADHESION FACE SIDE) [μm] | | | | | | | | | |
| W₃ (DISTANCE BETWEEN PAIR OF | 50 | 50 | 50 | 50 | 50 | 50 | 50 | N/A | N/A |
| RISER PART IN CROSS SECTION IN | | | | | | | | | |
| LONGITUDINAL DIRECTION PASSING | | | | | | | | | |
| THROUGH CENTER OF NOZZLE | | | | | | | | | |
| OPENING) [μm] | | | | | | | | | |
| D₁ (DIAMETER OF END OF NOZZLE | 30 | 30 | 30 | 30 | 40 | 30 | 30 | 30 | 30 |
| TAPERED PART ON EJECTION FACE | | | | | | | | | |
| SIDE) (DIAMETER OF END OF NOZZLE | | | | | | | | | |
| STRAIGHT PART ON ADHESION FACE | | | | | | | | | |
| SIDE) [μm] | | | | | | | | | |
| D₀ (SIZE OF NOZZLE OPENING) [μm] | 30 | 30 | 30 | 30 | 30 | 30 | 30 | 30 | 30 |
| h₀ (DISTANCE FROM NOZZLE OPENING | 20 | 30 | 50 | 60 | 50 | 15 | 65 | N/A | N/A |
| TO END OF RISER PART ON ADHESION | | | | | | | | | |
| FACE SIDE) [μm] | | | | | | | | | |
| h₁ (HEIGHT OF RISER PART) [μm] | 10 | 10 | 10 | 20 | 10 | 5 | 55 | N/A | N/A |
| NUMBER OF RISER PARTS | 2 | 1 | 1 | 1 | 1 | 2 | 2 | N/A | N/A |
| L (HEIGHT OF NOZZLE STRAIGHT | 0 | 10 | 30 | 30 | 35 | 0 | 0 | 0 | 0 |
| PART) [μm] | | | | | | | | | |
| θ₂ (ANGLE BETWEEN NOZZLE | N/A | 0 | 0 | 0 | 8 | N/A | N/A | N/A | N/A |
| STRAIGHT PART AND NOZZLE | | | | | | | | | |
| CENTRAL SHAFT) [°] | | | | | | | | | |
| EJECTION ANGLE [°] | 0.30 | 0.25 | 0.20 | 0.20 | 0.20 | 0.30 | 0.30 | 0.30 | 0.30 |
| MENISCUS STABILITY | AA | AA | AA | AA | AA | A | A | B | C |
| [UPPER LIMIT SPEED m/s] | (11) | (12) | (13) | (13) | (13) | (10) | (10) | (9) | (8) |
| DRIVE VOLTAGE [V] | 23.0 | 23.5 | 25.0 | 25.0 | 24.5 | 23.0 | 27.0 | 23.0 | 30.0 |

*1: EXAMPLE
*2: COMPARATIVE EXAMPLE

### [Evaluation]

When Example 1 is compared with Comparative Example 1, it is found that the nozzle channel 111 having excellent meniscus stability is obtained by providing the riser face 1112b in the nozzle tapered part 1112.

In addition, when Examples 1 and 6 are compared, it is found that the distance h₀ from the nozzle opening N to the end of the riser face 1112b on the attachment surface Bb side is preferably 20 μm or more. Further, when Examples 4 and 7 are compared, it is found that the distance h₀ from the nozzle opening N to the end of the riser face 1112b on the attachment surface Bb side is preferably 60 μm or less.

In addition, when Example 1 is compared with Examples 2 to 5, it is found that the channel resistance is increased and the drive voltage is increased by providing the nozzle straight part 1111. On the other hand, it is found that the nozzle channel 111 having a stable injection angle is formed by providing the nozzle straight part 1111.

In addition, in particular, when Example 5 is compared with Example 3, it is found that the channel resistance decreases and the drive voltage decreases by forming the nozzle straight part 1111 in a tapered shape.

In addition, when Comparative Example 1 is compared with Comparative Example 2, it is found that the channel resistance decreases and the drive voltage decreases by forming the opening of the nozzle channel 111 in the nozzle plate 110 on the attachment surface Bb side in an elongated shape.

### Technical Effects

As described hereinbefore, in the nozzle plate 110 according to the present embodiment, the pair of riser faces 1112b is provided in the nozzle tapered part 1112.

According to the configuration, the meniscus shape in the nozzle channel 111 is suppressed from expanding only in one direction. Therefore, as shown in FIGS. 6A and 6B, the spread of the meniscus shape can be uniformed. As a result, the stability of the meniscus shape is increased, resulting in the nozzle channel 111 having excellent ejection characteristics.

In addition, in the cross section in the longitudinal direction passing through the center of the nozzle opening N, the interval W₃ between the pair of riser faces 1112b is substantially the same as the distance W₂ in the left-right direction, which is the second direction, between the pair of surfaces constituting the longitudinal sides in the attachment surface Bb among the surfaces constituting the straight communication part 1113.

In the above configuration, a space having a substantially square shape in top view, which is formed of the riser faces 1112b and the surfaces parallel to the surfaces forming the long sides of the nozzle straight part 1111 among the surfaces forming the nozzle tapered part 1112, is formed in the vicinity of the nozzle opening N so as to have symmetry. Therefore, the nozzle channel 111 having excellent ejection characteristics is obtained.

Furthermore, the length h₀ from the ejection surface Ba to the end of the riser face 1112b on the side of the attachment surface Bb is equal to or greater than the maximum height to which the menisci rise.

In the above configuration, it is possible to prevent the meniscus from being broken due to the ink being drawn above the riser face 1112b and the ejection characteristics from deteriorating.

The distance h₀ from the ejection surface Ba to the end of the riser face 1112b on the side of the attachment surface Bb is 20 μm or more and 60 μm or less.

In the above configuration, the nozzle channel 111 securing both ejection characteristics and a volume is formed.

In addition, the nozzle straight part 1111 is provided in the nozzle channel 111.

In the above configuration, the nozzle channel 111 having more excellent ejection characteristics is obtained.

The nozzle plate 110 is made of a single-crystal silicon substrate.

In the configuration, the nozzle channel 111 has high precision.

Although an embodiment of the present invention and modification examples thereof have been described above, the description in the above-described embodiment and modification examples is a preferable example of the present invention and is not limited thereto.

### INDUSTRIAL APPLICABILITY

The present invention can be used for a nozzle plate, a liquid droplet ejection head, and a liquid droplet ejection device that can achieve both an increase in the density of nozzle openings and suitable ejection properties.

### REFERENCE SIGNS LIST

1 INKJET RECORDING DEVICE (LIQUID DROPLET EJECTION DEVICE)
10 INKJET HEAD (LIQUID DROPLET EJECTION HEAD)
110 NOZZLE PLATE
111 NOZZLE CHANNEL
1111 NOZZLE STRAIGHT PART
1112 NOZZLE TAPERED PART
1112a TAPERED FACE
1112b RISER FACE
1112c PLANAR PART
1113 STRAIGHT COMMUNICATION PART
1113a PAIR OF OPPOSING FACES
N NOZZLE OPENING
B SUBSTRATE
Ba EJECTION SURFACE (FIRST SURFACE)
Bb ATTACHMENT SURFACE (SECOND SURFACE)

1. A nozzle plate comprising:
a plurality of nozzle channels, in each of which a nozzle opening for ejecting liquid droplets is formed on a first surface of a substrate,
wherein each of the plurality of nozzle channels includes:
a nozzle tapered part having a channel area that gradually increases from the first surface toward a second surface that is opposite to the first surface, the channel area being a cross-sectional area perpendicular to a droplet ejection direction; and
a straight communication part that communicates with an end of the nozzle tapered part on a side of the second surface and includes a pair of opposing surfaces substantially parallel to each other,
wherein the straight communication part has a length in a first direction along the pair of opposing surfaces that is longer than a length in a second direction perpendicular to the first direction on the second surface,
wherein the nozzle tapered part includes: a tapered face that is inclined from an end in the first direction toward a center of the nozzle opening; and a pair of riser faces with the nozzle opening in between, the pair of riser faces each forming a step,
wherein each of the pair of riser faces is a vertical surface parallel to a nozzle central axis or an inclined surface which forms, with the nozzle central axis, an angle smaller than an angle formed by the tapered part with the nozzle central axis.

2. The nozzle plate according to claim 1,
wherein a distance between the pair of riser faces in a cross section in the first direction passing the center of the nozzle opening is equal to the length in the second direction.

3. The nozzle plate according to claim 1,
wherein a length from the first surface to an end of the pair of riser faces on the side of the second surface is equal to or greater than a maximum height to which a meniscus rises.

4. The nozzle plate according to claim 3,
wherein the length from the first surface to the end of the pair of riser faces on the side of the second surface is 20 μm or more.

5. The nozzle plate according to claim 3,
wherein the length from the first surface to the end of the pair of riser faces on the side of the second surface is 60 μm or more.

6. The nozzle plate according to claim 1,
wherein each of the nozzle channels includes a nozzle straight part continuous with an end of the nozzle tapered part on a side of the first surface;
wherein a surface of the nozzle straight part forms a substantially constant angle with an axis parallel to a nozzle central axis,
wherein a channel area of an end of the nozzle straight part on the side of the first surface is equal to or smaller than a channel area of an end of the nozzle straight part on the side of the second surface.

7. The nozzle plate according to claim 1,
wherein the substrate is made of single-crystal silicon,
wherein the nozzle tapered part is formed of a part of a {100} plane and a {111} plane,
wherein the straight communication part is formed of a part of the {100} plane.

8. The nozzle plate according to claim 1, further comprising:
a planar part having a surface parallel to the first surface and the second surface between an end of the straight communication part on a side of the first surface side and an end of the nozzle tapered part on the side of the second surface.

9. A liquid droplet ejection head to be mounted on a liquid droplet ejection device, the liquid droplet ejection head comprising:
the nozzle plate according to claim 1.

10. A liquid droplet ejection device comprising:
the liquid droplet ejection head according to claim 9.
